(19) United States
(12) Patent Application Publication
(10) Pub. No.: US 2025/0126758 A1
(43) Pub. Date: Apr. 17, 2025

(54) REAR-DOOR HEAT DISSIPATION SYSTEM WITH HORIZONTALLY ARRANGED AND SERIES-CONNECTED DESIGN

(71) Applicant: Man Zai Industrial Co., LTD., Tainan City (TW)

(72) Inventors: Cheng-Chien WAN, Tainan City (TW); Cheng-Jui WAN, Tainan City (TW); Chun-Hsien SU, Tainan City (TW); Hui-Fen HUANG, Tainan City (TW); Fong Jou TU, Tainan City (TW); Chi Cheng CHEN, Tainan City (TW); Chuan Meng WANG, Tainan City (TW)

(21) Appl. No.: 18/822,829

(22) Filed: Sep. 3, 2024

(30) Foreign Application Priority Data
Oct. 17, 2023 (TW) 112211130
May 28, 2024 (TW) 113205447

(51) Int. Cl. H05K 7/20

(52) U.S. Cl. CPC H05K 7/20736; H05K 7/20154

(57) ABSTRACT

The present invention provides a rear-door heat dissipation system with a horizontally arranged and series-connected design comprising a heat dissipation cabinet, at least one condenser unit, and a heat dissipation device. The heat dissipation cabinet is provided therein with an active heat source device and a cabinet back door on one side of the heat dissipation cabinet, wherein the cabinet back door is provided with an air circulation unit. The condenser unit is provided on the cabinet back door, comprising a plurality of condensers. Wherein the circulation tube system of each of the condensers comprises a first and second main-channel aluminum tube, and aluminum flat tubes. Each aluminum flat tube has two ends respectively connecting to the first and second main-channel aluminum tube. An airflow channel is formed between each two adjacent aluminum flat tubes to enable air circulation, and each airflow channel is provided with an aluminum fin. The heat dissipation device connects to the circulation tube system and dissipate heat through receiving the thermal conduction medium.

### BACKGROUND OF THE INVENTION

### 1. Technical Field

The present invention relates to a rear-door heat dissipation system. More particularly, the invention relates to a rear-door heat dissipation system with a horizontally arranged and series-connected design in which the airflow channels have relatively great lengths to help enhance heat dissipation efficiency.

### 2. Description of Related Art

A rear-door heat dissipation system is a cabinet designed specifically for high-heat equipment (such as high-precision computation equipment, storage equipment, or an energy storage system (e.g., a lithium-iron battery)) and works mainly by using the heat dissipation device (e.g., a heat exchanger) on the cabinet back door to cool, i.e., to lower the temperature of, the environment and electrical devices in the cabinet. With the advancement of technology and the growing demand for computation power, the density of the servers and storage equipment in high-end data centers has been increasing. As a result, the conventional air-cooling methods may fail to provide the cooling performance required, and great importance is therefore attached to the design of heat dissipation cabinets.

A rear-door heat dissipation system generally includes a heat exchanger provided on the back of the cabinet to produce a cooling effect by way of a liquid coolant. When the equipment in the cabinet is in operation, hot air flows to the back of the cabinet and is cooled by the heat exchanger. To ensure cooling efficiency, the cabinet typically uses a sealed design so that hot air dissipated from inside the cabinet by the heat exchanger will not reenter the cabinet. In short, rear-door heat dissipation systems provide a highly efficient cooling method and are particularly suitable for high-density data center environments.

Generally, the heat exchanger on the back door of a conventional rear-door heat dissipation system performs heat exchange through a structure that includes copper tubes inserted through aluminum fins. Such design, however, results in a relatively low flow rate and internal impedance, which lead to insufficient heat exchange and hence poor heat dissipation.

### BRIEF SUMMARY OF THE INVENTION

The primary objective of the present invention is to provide a rear-door heat dissipation system with a horizontally arranged and series-connected design comprising a heat dissipation cabinet, at least one condenser unit, and a heat dissipation device. The heat dissipation cabinet is provided therein with an active heat source device, the heat dissipation cabinet being further provided with a cabinet back door on an arbitrary side of the heat dissipation cabinet, wherein the cabinet back door is provided with an air circulation unit. At least one condenser unit is provided on the cabinet back door and corresponding in position to the air circulation unit in order for a thermal conduction medium in the at least one condenser unit to receive heat from an airflow passing through the at least one condenser unit, each said condenser unit comprising a plurality of condensers, wherein each said condenser has a circulation tube system comprising a first main-channel aluminum tube, a second main-channel aluminum tube, and a plurality of aluminum flat tubes each having one end in communication with the first main-channel aluminum tube and an opposite end in communication with the second main-channel aluminum tube, wherein an airflow channel is formed between each two adjacent said aluminum flat tubes to enable air circulation, and each said airflow channel is provided therein with an aluminum fin, and wherein the condensers in each said condenser unit are horizontally arranged, and the airflow channels of the condensers in each said condenser unit are connected in series. The heat dissipation device in communication with the circulation tube systems is configured to receive the thermal conduction medium in the circulation tube systems and dissipate heat from the thermal conduction medium received.

Furthermore, the number of the plurality of condensers in each said condenser unit is two or greater than two.

Furthermore, the number of the at least one condenser unit is plural, and the plural condenser units are sequentially arranged in a downward direction.

Furthermore, the heat dissipation device comprises an inflow main duct and a return-flow main duct, and wherein the inflow main duct is connected to at least one input of the circulation tube systems of each of the plural condenser units, and the return-flow main duct is connected to at least one output of the circulation tube systems of each of the plural condenser units.

Furthermore, at least one separation wall is provided in each said first main-channel aluminum tube and/or each said second main-channel aluminum tube of an arbitrary one, or each of several, of the plural condenser units such that each said first main-channel aluminum tube provided with at least one said separation wall and/or each said second main-channel aluminum tube provided with at least one said separation wall is divided into at least two cavities sequentially arranged in the downward direction.

Furthermore, the input of the circulation tube systems of each of the plural condenser units is provided at a said first main-channel aluminum tube, and the output of the circulation tube systems of each of the plural condenser units is provided at a said second main-channel aluminum tube.

Furthermore, the input and the output of the circulation tube systems of each of the plural condenser units are provided at a said first main-channel aluminum tube.

Furthermore, the air circulation unit comprises a channel provided in the cabinet back door and a fan provided in the channel.

Furthermore, the first main-channel aluminum tubes, the second main-channel aluminum tubes, and the aluminum flat tubes are formed by aluminum extrusion.

Furthermore, each of the condensers has a thickness ranging from 10 mm to 40 mm.

For that a plurality of condensers are horizontally arranged and their respective airflow channels are connected in series, and that an air circulation unit can guide cool air through the series-connected airflow channels to promote sufficient heat exchange between the cool air and the thermal conduction medium in the condensers, the present invention enhances the efficiency and effect of heat dissipation.

### BRIEF DESCRIPTION OF THE SEVERAL VIEWS OF THE DRAWINGS

FIG. 1 is a perspective view of a rear-door heat dissipation system with a horizontally arranged and series-connected design according to the present invention.

FIG. 2 schematically shows how the condenser unit and the air circulation unit in the present invention are arranged.

FIG. 3 is a perspective view of an embodiment of the condenser unit in the present invention.

FIG. 4 is another perspective view of the embodiment of the condenser unit in FIG. 3.

FIG. 5 is a sectional view taken along line MM in FIG. 3.

FIG. 6 is a sectional view taken along line NN in FIG. 3.

FIG. 7 schematically shows, in front view, the loop design of an embodiment of a rear-door heat dissipation system with a horizontally arranged and series-connected design according to the present invention.

FIG. 8 schematically shows the loop design in FIG. 7 in top view.

FIG. 9 schematically shows, in front view, the loop design of another embodiment of a rear-door heat dissipation system with a horizontally arranged and series-connected design according to the present invention.

FIG. 10 schematically shows the loop design in FIG. 9 in top view.

FIG. 11 schematically shows, in front view, the loop design of yet another embodiment of a rear-door heat dissipation system with a horizontally arranged and series-connected design according to the present invention. The rear-door heat dissipation system in this embodiment is further provided with a pressurization device.

### DETAILED DESCRIPTION OF THE INVENTION

The details and technical solution of the present invention are hereunder described with reference to accompanying drawings. For illustrative sake, the accompanying drawings are not drawn to scale. The accompanying drawings and the scale thereof are not restrictive of the present invention.

As used herein, the term “on one side” or “on an arbitrary side” may refer to being on the left side, right side, front side, or rear side of an object; or being at an arbitrary position adjacent to the object; or being directly or indirectly connected to the object; the present invention has no limitation in this regard.

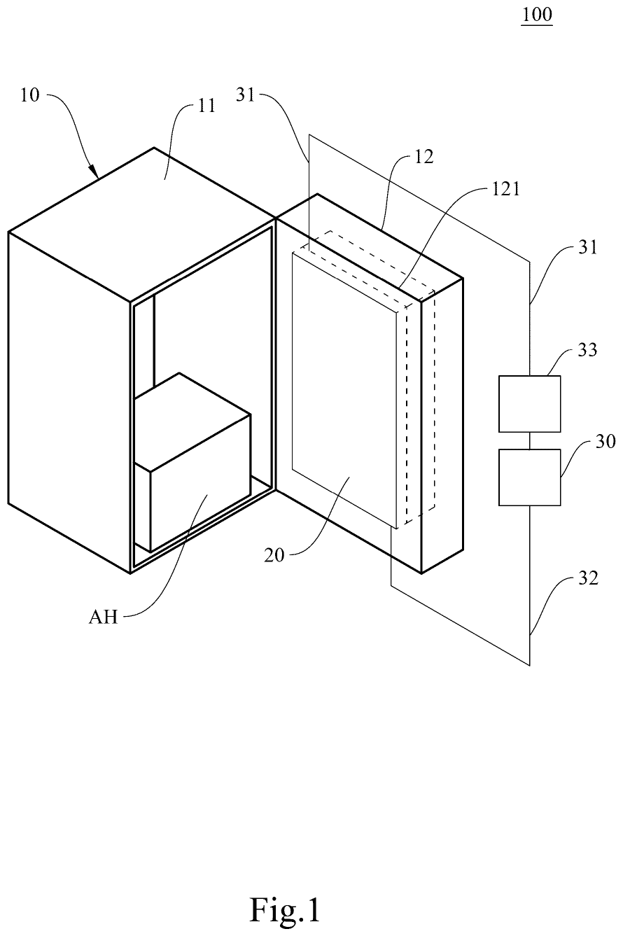

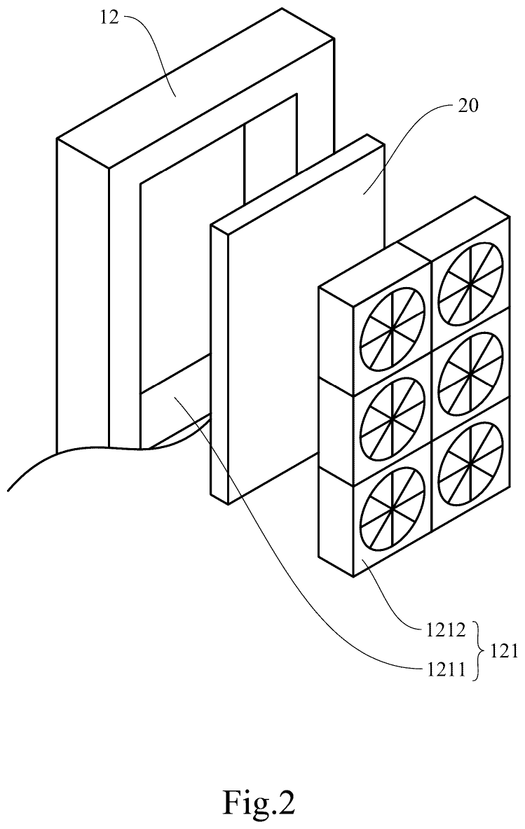

The present invention is described below with reference to specific embodiments. To begin with, please refer to FIG. 1 and FIG. 2, which are respectively a perspective view of a rear-door heat dissipation system with a horizontally arranged and series-connected design according to the invention and a schematic drawing showing how the condenser unit and the air circulation unit in the invention are arranged.

As shown in FIG. 1 and FIG. 2, the present invention discloses a rear-door heat dissipation system 100 with a horizontally arranged and series-connected design. One feature of the rear-door heat dissipation system 100 is that heat exchange equipment is provided on the back door of a cabinet to increase the efficiency of heat dissipation and thereby preventing the electronic equipment in the cabinet from overheating. The rear-door heat dissipation system 100 with a horizontally arranged and series-connected design essentially includes a heat dissipation cabinet 10, at least one condenser unit 20 provided on the heat dissipation cabinet 10, and a heat dissipation device 30 connected to the condenser unit 20. The aforesaid electronic equipment may be power supply equipment, energy storage equipment, or other high-temperature devices that are used in, for example but not limited to, a data center or server room and generate a large amount of heat.

The heat dissipation cabinet 10 includes a cabinet body 11 and a cabinet back door 12 coupled to an arbitrary side of the cabinet body 11. An active heat source device AH is provided in the cabinet body 11 of the heat dissipation cabinet 10. In one embodiment, the active heat source device AH may be any high-temperature device stated above, such as but not limited to a server, a motherboard, a circuit board, power supply equipment, an energy-storing battery, or other high-temperature devices that generate heat. In one embodiment, the cabinet back door 12 is designed as, for example but not limited to, a door panel and may be provided on an arbitrary side of the cabinet body 11 so that access to the interior space of the cabinet body 11 can be provided or cut off by opening or closing the cabinet back door 12. In one embodiment, the cabinet back door 12 is coupled to the cabinet body 11 by, for example but not limited to, pivotal connection, slide rails, threaded connection, or other mounting methods or structures.

The cabinet back door 12 is provided with an air circulation unit 121, and an air channel is provided in, for example but not limited to, the side opposing the cabinet back door 12 or an arbitrary side (e.g., the left, right, front, or rear side) of the cabinet body 11 so that cool air can be drawn into the cabinet body 11 through the aforesaid side thereof, flow past/through the active heat source device AH in the cabinet body 11, and then be discharged through the air circulation unit 121 as well as the venting design of the condenser unit 20 on the cabinet back door 12. In one embodiment, an appropriate portion of the cabinet body 11 may be sealed to prevent external substances (e.g., dust) from entering the cabinet body 11, thereby ensuring the safety of the active heat source device AH inside.

The condenser unit 20 is provided on the cabinet back door 12 at a position corresponding to the air circulation unit 121 so that a thermal conduction medium can receive heat from the airflow passing through the condenser unit 20. In one embodiment, the air circulation unit 121 includes a channel 1211 provided in the cabinet back door 12 and a fan 1212 provided in the channel 1211. In one embodiment, the fan 1212 has a planar configuration and is provided vertically in the channel 1211 such that the air input side or the air output side of the fan 1212 faces the airflow channels of the condenser unit 20. In other embodiments, the fan 1212 may be, for example but not limited to, a turbofan, a forced-draft fan, or a device whose function is the same as or similar to that of either of the foregoing. In the embodiment shown in FIG. 2, the fan 1212 is provided on the outer side of the condenser unit 20 (i.e., with the air input side of the fan 1212 facing the airflow channels of the condenser unit 20). Depending on actual configuration requirements, however, the condenser unit 20 may be provided on the outer side of the fan 1212 instead (i.e., with the air output side of the fan 1212 facing the airflow channels of the condenser unit 20). The present invention has no limitation on variations such as those of the foregoing embodiments.

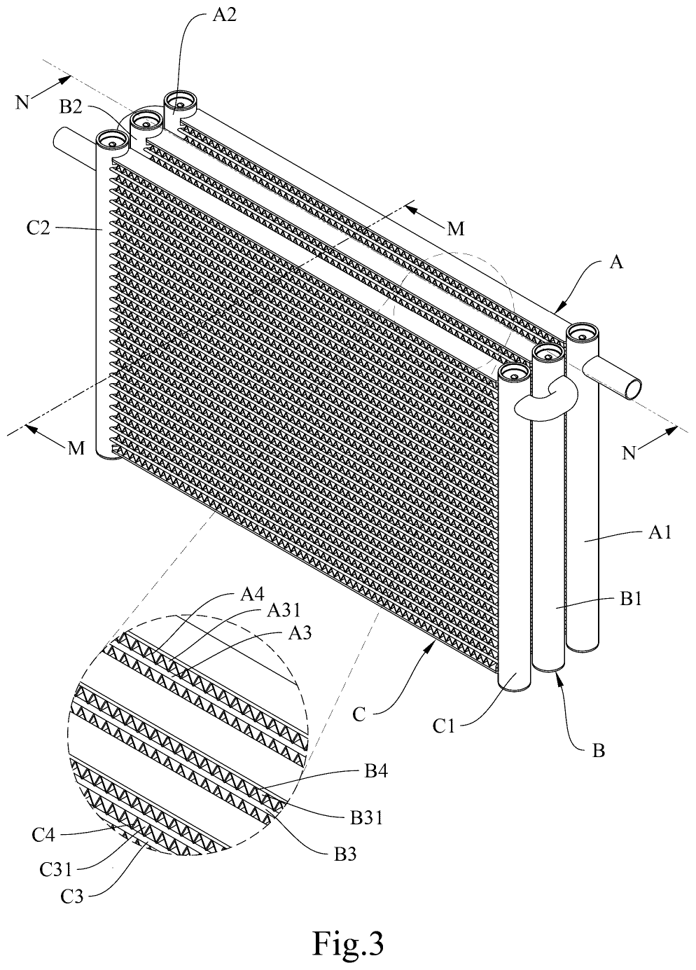

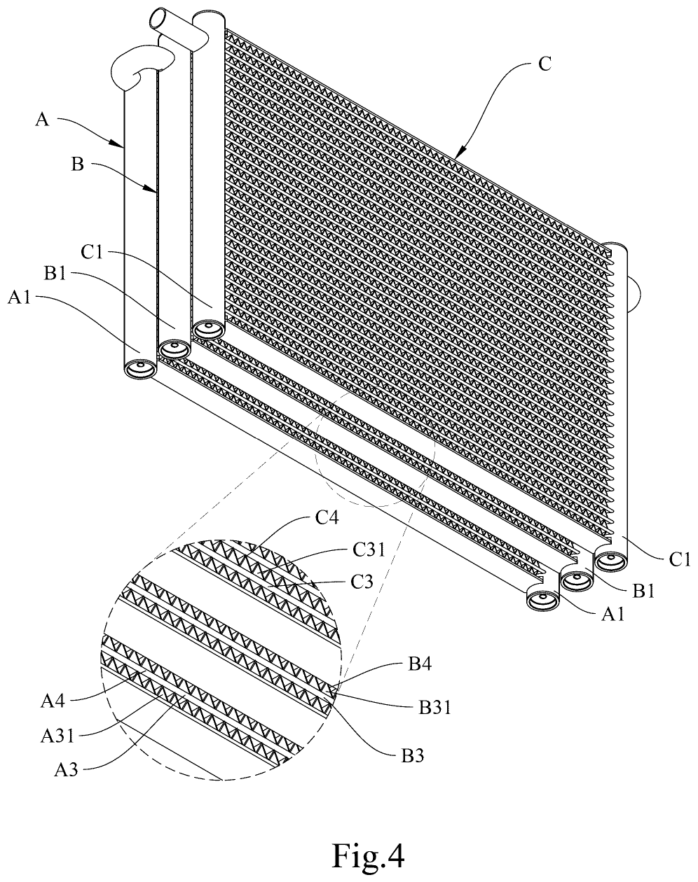

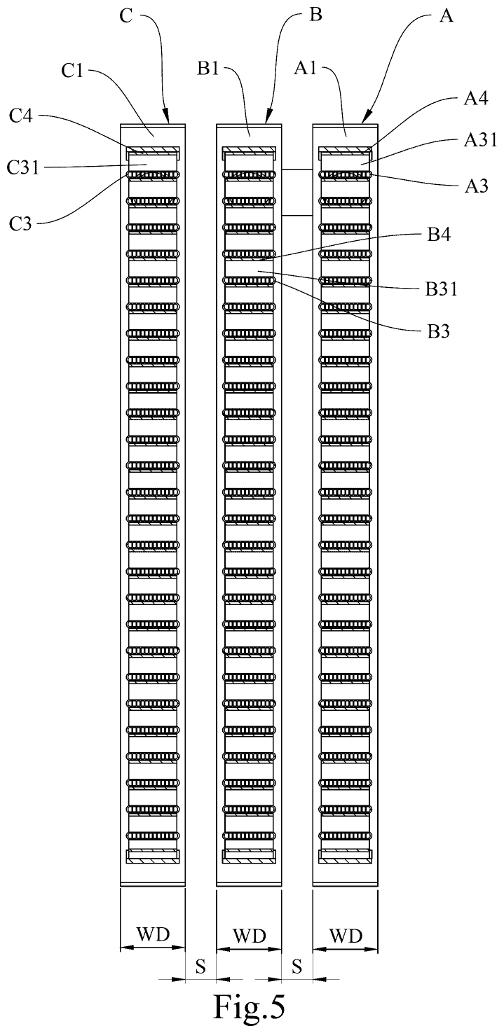

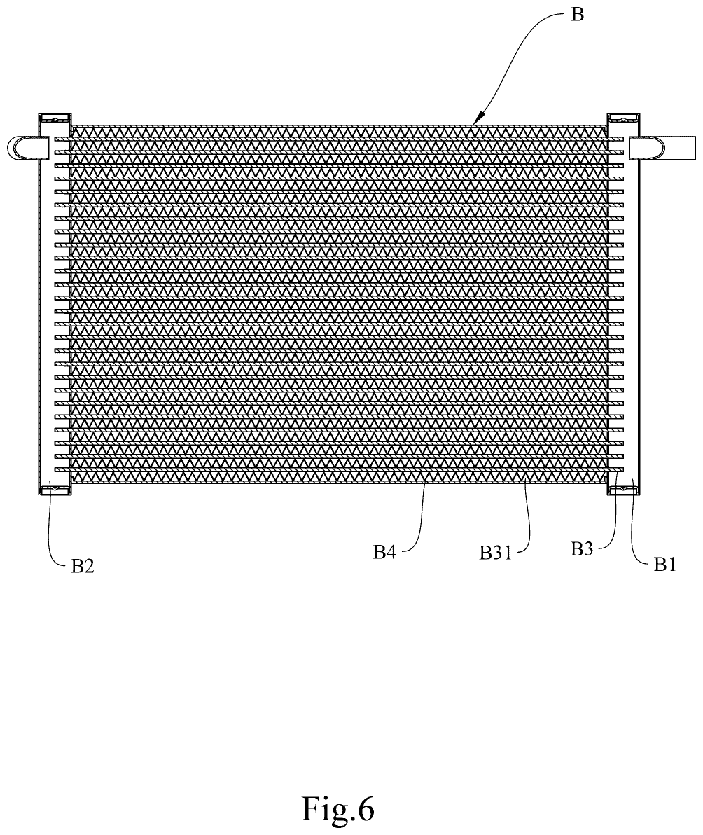

Please refer to FIG. 3 to FIG. 6 for a perspective view of an embodiment of the condenser unit in the present invention, another perspective view of the embodiment of the condenser unit in FIG. 3, a sectional view taken along line MM in FIG. 3, and a sectional view taken along line NN in FIG. 3.

As shown in FIG. 3 to FIG. 6, each condenser unit 20 in the present invention includes a plurality of condensers that are horizontally arranged and whose airflow channels are connected in series. The number of the plurality of condensers in each condenser unit 20 may be two or more than two. In the embodiment shown in FIG. 3 to FIG. 6, the number of the condensers in each condenser unit 20 is three. Furthermore, the phrase “whose airflow channels are connected in series” refers to a design in which: the outlets of the airflow channels of a condenser A are aligned with or connected to the inlets of the airflow channels of a condenser B, and the outlets of the airflow channels of the condenser B are aligned with or connected to the inlets of the airflow channels of a condenser C such that not only are the three condensers A, B, and C horizontally arranged, but also the airflow channels of the three condensers A, B, and C are connected in series. In an embodiment that is different from the embodiment shown in FIG. 3 to FIG. 6, each condenser unit 20 includes two or more than three condensers (not shown). By increasing the number of the horizontally arranged condensers, the connected lengths of the series-connected airflow channels of the condensers can be increased. The invention has no limitation on the number of the plurality of condensers in each condenser unit.

As shown in FIG. 3 to FIG. 6, the condensers A, B, and C are horizontally arranged and have their respective airflow channels connected in series so as to achieve considerable heat exchange efficiency. The thickness WD of each condenser A, B, or C is in the range of 10 mm to 40 mm. The thickness WD may be, for example but not limited to, 10 mm, 11 mm, 12 mm, 13 mm, 14 mm, 15 mm, 16 mm, 17 mm, 18 mm, 19 mm, 20 mm, 21 mm, 22 mm, 23 mm, 24 mm, 25 mm, 26 mm, 27 mm, 28 mm, 29 mm, 30 mm, 31 mm, 32 mm, 33 mm, 34 mm, 35 mm, 36 mm, 37 mm, 38 mm, 39 mm, or 40 mm; the present invention has no limitation in this regard. According to the foregoing design of the invention, a condenser unit 20 with two series-connected condensers already can achieve about 85% of the heat exchange efficiency of a condenser unit 20 with the three series-connected condensers A, B, and C; therefore, by connecting the three condensers A, B, and C or more than three condensers in series, the invention can provide even higher heat exchange efficiency. In one embodiment, there may be an interval S between each two adjacent series-connected condensers, and the invention has no limitation on the actual value of the interval S.

The condenser A has a circulation tube system that includes a first main-channel aluminum tube A1, a second main-channel aluminum tube A2, and a plurality of aluminum flat tubes A3 each communicating with the first main-channel aluminum tube A1 at one end and the second main-channel aluminum tube A2 at the other end. An airflow channel A31 is formed between each two adjacent aluminum flat tubes A3 to enable air circulation, and each airflow channel A31 is provided therein with an aluminum fin A4. The condenser B has a circulation tube system that includes a first main-channel aluminum tube B1, a second main-channel aluminum tube B2, and a plurality of aluminum flat tubes B3 each communicating with the first main-channel aluminum tube B1 at one end and the second main-channel aluminum tube B2 at the other end. An airflow channel B31 is formed between each two adjacent aluminum flat tubes B3 to enable air circulation, and each airflow channel B31 is provided therein with an aluminum fin B4. The condenser C has a circulation tube system that includes a first main-channel aluminum tube C1, a second main-channel aluminum tube C2, and a plurality of aluminum flat tubes C3 each communicating with the first main-channel aluminum tube C1 at one end and the second main-channel aluminum tube C2 at the other end. An airflow channel C31 is formed between each two adjacent aluminum flat tubes C3 to enable air circulation, and each airflow channel C31 is provided therein with an aluminum fin C4. Each aluminum flat tube A3, B3, or C3 is provided therein with a plurality of capillaries. The capillaries allow passage of a thermal conduction medium so that exchange of heat can take place between the thermal conduction medium and the air in the airflow channels outside through the walls of the capillaries. The capillary design also increases the internal impedance of the condensers A, B, and C. The first main-channel aluminum tubes A1, B1, and C1, the second main-channel aluminum tubes A2, B2, and C2, and the aluminum flat tubes A3, B3, and C3 may be formed by aluminum extrusion; the present invention has no limitation in this regard.

The heat dissipation device 30 is in communication with the circulation tube systems of the at least one condenser unit 20 and receives the thermal conduction medium in the circulation tube systems in order to dissipate heat. The heat dissipation device 30 includes an inflow main duct 31 and a return-flow main duct 32. The inflow main duct 31 is connected to at least one input of the circulation tube systems of each of the at least one condenser unit 20, and the return-flow main duct 32 is connected to at least one output of the circulation tube systems of each of the at least one condenser unit 20. In one embodiment, the heat dissipation device 30 may be, for example but not limited to, a freezing/air-conditioning unit, a cooling tower, a fan cooler, a heat exchanger, or a device whose function is the same as or similar to that of any of the foregoing.

The circulation tube systems of the plural condensers in each condenser unit are connected in series, too. The phrase “the circulation tube systems . . . are connected in series” refers to the internal circulation channels through which the thermal conduction medium is circulated but not to the airflow channels outside those internal circulation channels. In the embodiment shown in FIG. 3 to FIG. 6, the first main-channel aluminum tube A1 is connected to the inflow main duct 31; the second main-channel aluminum tube A2 is connected to the second main-channel aluminum tube B2 through an additional channel (e.g., a through hole or an additional tube) such that the internal cavity of the second main-channel aluminum tube A2 and the internal cavity of the second main-channel aluminum tube B2 are connected; the first main-channel aluminum tube B1 is connected to the first main-channel aluminum tube C1 through an additional channel (e.g., a through hole or an additional tube) such that the internal cavity of the first main-channel aluminum tube B1 and the internal cavity of the first main-channel aluminum tube C1 are connected; and the second main-channel aluminum tube C2 is connected to the return-flow main duct 32. Thus, the circulation tube systems of the condensers A, B, and C are not only in communication with the inflow main duct 31 and the return-flow main duct 32, but also connected in series. In another embodiment, it is the second main-channel aluminum tube A2 that is connected to the inflow main duct 31; the first main-channel aluminum tube A1 is connected to the first main-channel aluminum tube B1 through an additional channel (e.g., a through hole or an additional tube) such that the internal cavity of the first main-channel aluminum tube Al and the internal cavity of the first main-channel aluminum tube B1 are connected; the second main-channel aluminum tube B2 is connected to the second main-channel aluminum tube C2 through an additional channel (e.g., a through hole or an additional tube) such that the internal cavity of the second main-channel aluminum tube B2 and the internal cavity of the second main-channel aluminum tube C2 are connected; and the return-flow main duct 32 is connected to the first main-channel aluminum tube C1 instead. Thus, the circulation tube systems of the condensers A, B, and C in this alternative embodiment are also in communication with the inflow main duct 31 and the return-flow main duct 32 and series-connected. The present invention has no limitation on variations such as those of the foregoing embodiments.

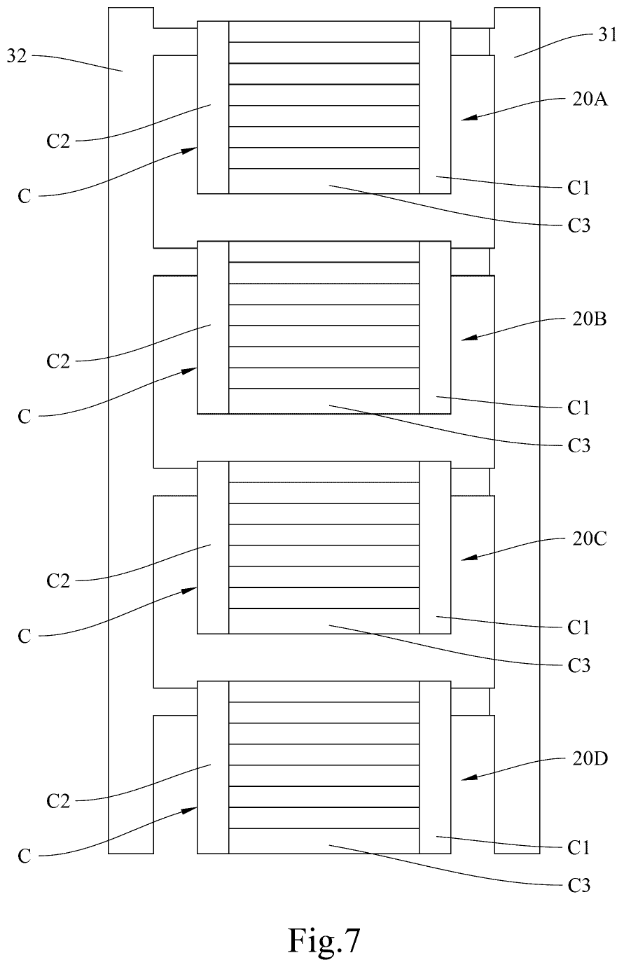

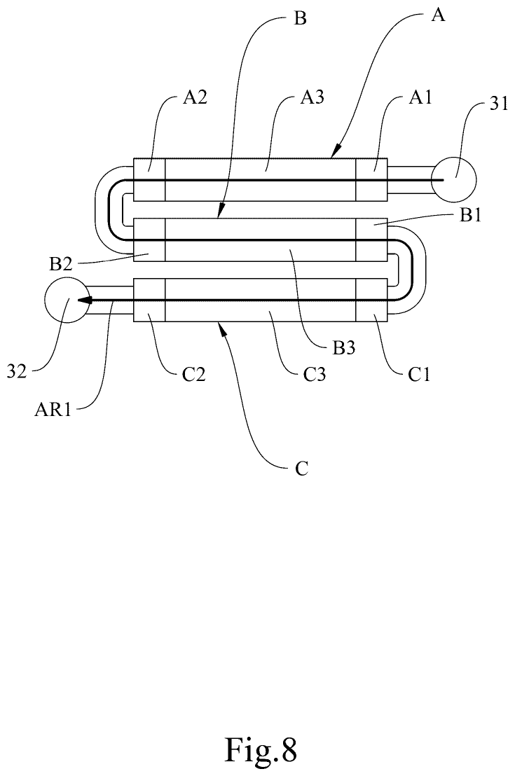

Please refer to FIG. 7 and FIG. 8 for schematic drawings that show, in front view and top view respectively, the loop design of an embodiment of a rear-door heat dissipation system with a horizontally arranged and series-connected design according to the present invention.

As shown in FIG. 7 and FIG. 8, the rear-door heat dissipation system 100 with a horizontally arranged and series-connected design includes a plurality of condenser units 20 that are sequentially arranged in a downward direction, i.e., one above the other. In this embodiment, there are four condenser units 20A, 20B, 20C, and 20D sequentially arranged in a downward direction. Each of the condenser units 20A, 20B, 20C, and 20D includes the aforesaid three condensers A, B, and C, which are horizontally arranged, have series-connected airflow channels, and are connected in series as well as to the inflow main duct 31 and the return-flow main duct 32. Specifically, however, the three condensers A, B, and C in each condenser unit are provided independently from one another as far as their respective circulation tube systems are concerned.

Based on the foregoing configuration of the condenser units 20A, 20B, 20C, and 20D, this embodiment includes four loops that are sequentially arranged in the downward direction, and the thermal conduction medium delivery path of each loop is as follows, as indicated by the arrow AR1: inflow main duct 31→first main-channel aluminum tube A1→aluminum flat tubes A3→second main-channel aluminum tube A2→second main-channel aluminum tube B2→aluminum flat tubes B3→first main-channel aluminum tube B1→first main-channel aluminum tube C1→aluminum flat tubes C3→second main-channel aluminum tube C2→return-flow main duct 32. Thus, circulation can take place through the loops of the four condenser units 20A, 20B, 20C, and 20D. In this embodiment, the input of the circulation tube systems of each of the condenser units 20A, 20B, 20C, and 20D is provided at the first main-channel aluminum tube Al of the corresponding condenser A, and the output of the circulation tube systems of each of the condenser units 20A, 20B, 20C, and 20D is provided at the second main-channel aluminum tube C2 of the corresponding condenser C.

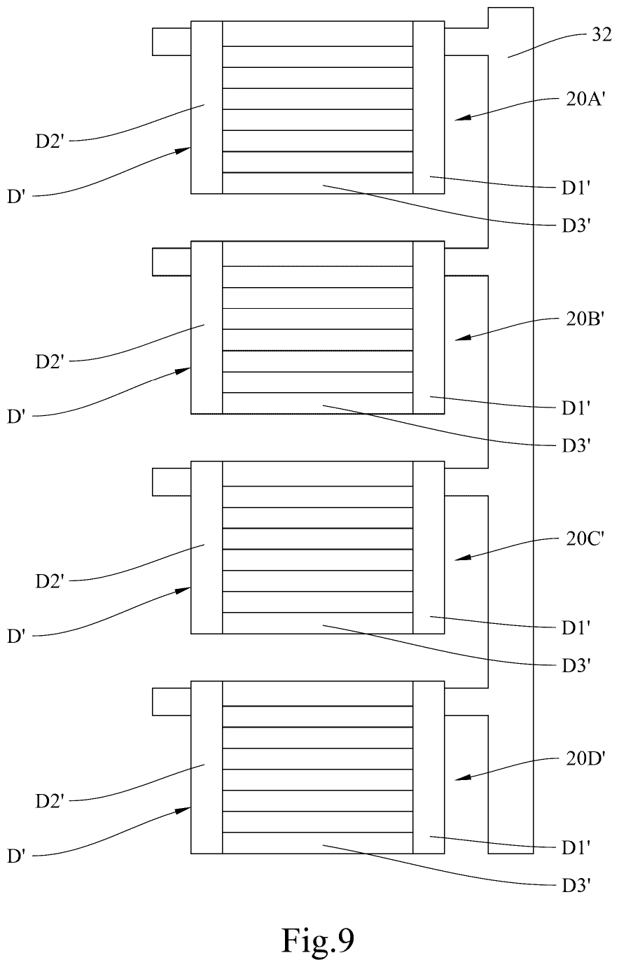

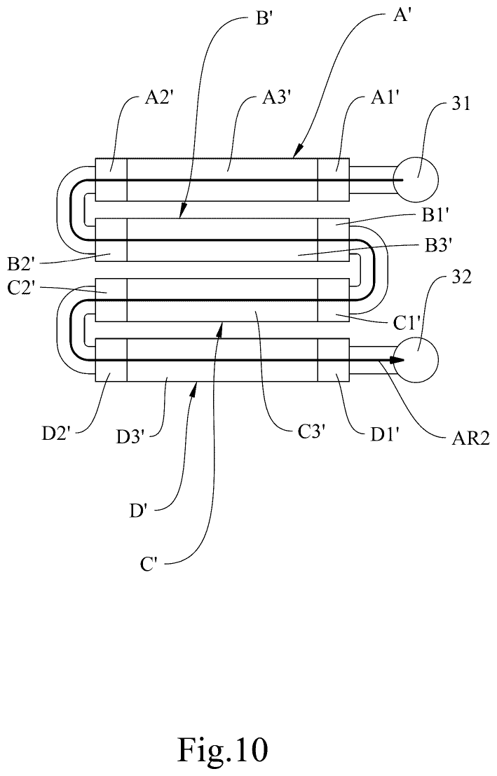

Please refer to FIG. 9 and FIG. 10 for schematic drawings that show, in front view and top view respectively, the loop design of another embodiment of a rear-door heat dissipation system with a horizontally arranged and series-connected design according to the present invention.

As shown in FIG. 9 and FIG. 10, this embodiment is different from the previous one in that each of the four condenser units 20A′, 20B′, 20C′, and 20D′, which are sequentially arranged in a downward direction, includes four condensers A′, B′, C′, and D′ that are horizontally arranged with series-connected airflow channels, and are connected in series as well as to the inflow main duct 31 and the return-flow main duct 32. Specifically, however, the four condensers A′, B′, C′, and D′ in each condenser unit are provided independently from one another as far as their respective circulation tube systems are concerned,

Based on the foregoing configuration of the condenser units 20A′, 20B′, 20C′, and 20D′, this embodiment includes four loops that are sequentially arranged in the downward direction, and the thermal conduction medium delivery path of each loop is as follows, as indicated by the arrow AR2: inflow main duct 31→first main-channel aluminum tube A1′→aluminum flat tubes A3′→second main-channel aluminum tube A2′→second main-channel aluminum tube B2′→aluminum flat tubes B3′→first main-channel aluminum tube B1′→first main-channel aluminum tube C1′→aluminum flat tubes C3′→second main-channel aluminum tube C2′→second main-channel aluminum tube D2′→aluminum flat tubes D3′→first main-channel aluminum tube D1′→return-flow main duct 32. Thus, circulation can take place through the loops of the four condenser units 20A′, 20B′, 20C′, and 20D′. In this embodiment, the input of the circulation tube systems of each of the condenser units 20A′, 20B′, 20C′, and 20D′ is provided at the first main-channel aluminum tube A1′ of the corresponding condenser A′, and the output of the circulation tube systems of each of the condenser units 20A′, 20B′, 20C′, 20D′ is provided at the first main-channel aluminum tube D′ of the corresponding condenser D′.

In an embodiment that is different from the previous ones, there may be at least three or more than three condenser units 20 (for example but not limited to three, four, five, six, seven, eight, nine, ten, or more than ten condenser units 20) that are sequentially arranged in a downward direction. By increasing the number of split flows formed in the longitudinal direction (i.e., the downward direction), with each condenser unit 20 including at least two horizontally arranged condensers whose airflow channels are connected in series, the efficiency of heat exchange can be increased. In one embodiment, there are at least ten, eleven, twelve, thirteen, fourteen, or fifteen condenser units 20 that are sequentially arranged in the longitudinal direction, and each condenser unit 20 includes the three horizontally arranged condensers A, B, and C, whose airflow channels are connected in series; this configuration greatly enhances the overall heat exchange efficiency, and hence the heat dissipation efficiency, of the rear-door heat dissipation system 100 with a horizontally arranged and series-connected design.

In an embodiment that is different from the previous ones, at least one separation wall (not shown) is provided in each first main-channel aluminum tube and each second main-channel aluminum tube of an arbitrary one, or each of several, of the condenser units such that each of those first and second main-channel aluminum tubes is divided by the corresponding at least one separation wall into at least two cavities that are sequentially arranged in a downward direction. In an embodiment that is different from the previous ones, at least one separation wall (not shown) is provided in each first main-channel aluminum tube or each second main-channel aluminum tube of an arbitrary one, or each of several, of the condenser units such that each first or second main-channel aluminum tube provided with at least one separation wall is divided thereby into at least two cavities that are sequentially arranged in a downward direction. The locations and/or number of the separation walls in the present invention can be adjusted according to actual loop design requirements, and the invention has no limitation on variations such as those of the foregoing embodiments.

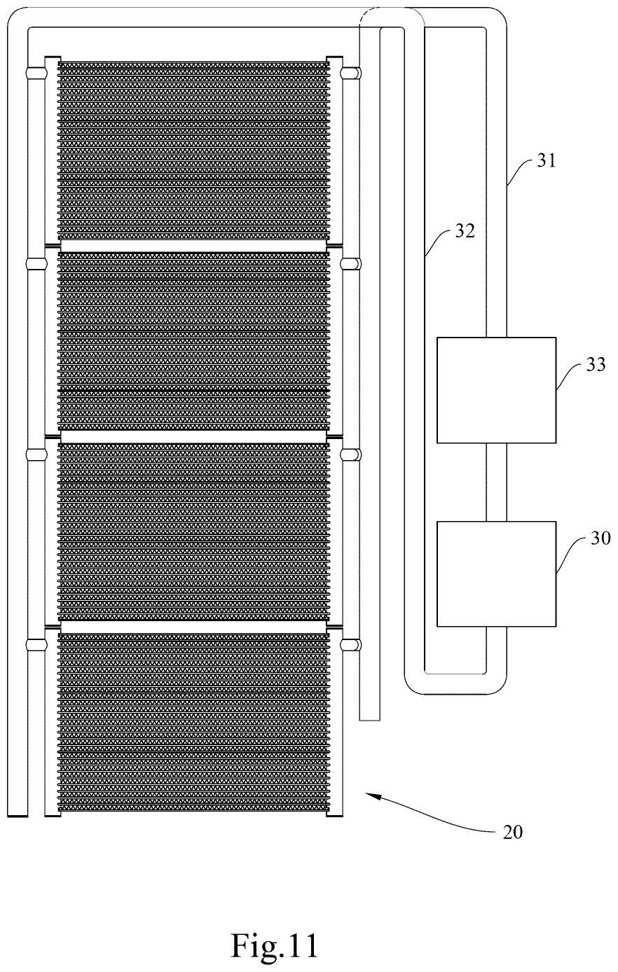

Please refer to FIG. 11 for a schematic drawing that shows, in front view, the loop design of yet another embodiment of a rear-door heat dissipation system with a horizontally arranged and series-connected design according to the present invention.

To deliver the thermal conduction medium into the condenser units 20, the heat dissipation device 30 may further include a pressurization device 33 that is connected to, for example but not limited to, the inflow main duct 31 as shown in FIG. 11, the return-flow main duct 32, or an arbitrary tube in communication with the inflow main duct 31 or the return-flow main duct 32, so as to pressurize the tubes and thereby guiding or pushing the thermal conduction medium in the circulation tube systems of the condenser units 20, the objective being to make the thermal conduction medium flow in circulation. In one embodiment, the pressurization device 33 may be, for example but not limited to, a centrifugal pump, a screw pump, a piston pump, a diaphragm pump, a gear pump, a magnetic drive pump, a convection pump, a submersible pump, a jet pump, a rotary vane pump, or a device whose function is the same as or similar to that of any of the foregoing.

While various loop designs have been described above, the present invention allows adjustment to be made to the number of condenser units sequentially arranged in a downward direction, to the number of horizontally arranged condensers whose airflow channels are connected in series, to the positions at which the heat dissipation device is connected to the at least one condenser unit, and/or to the sizes of the tubes in order to meet practical needs; the invention has no limitation on variations in the foregoing aspects.

According to the above, the present invention is designed as such that a plurality of condensers are horizontally arranged and their respective airflow channels are connected in series, and that an air circulation unit can guide cool air through the series-connected airflow channels to promote sufficient heat exchange between the cool air and the thermal conduction medium in the condensers, thereby enhancing the efficiency and effect of heat dissipation.

The above is the detailed description of the present invention. However, the above is merely the preferred embodiment of the present invention and cannot be the limitation to the implement scope of the invention, which means the variation and modification according to the present invention may still fall into the scope of the present invention.

What is claimed is:

1. A rear-door heat dissipation system with a horizontally arranged and series-connected design, comprising:
a heat dissipation cabinet provided therein with an active heat source device, the heat dissipation cabinet being further provided with a cabinet back door on an arbitrary side of the heat dissipation cabinet, wherein the cabinet back door is provided with an air circulation unit;
at least one condenser unit provided on the cabinet back door and corresponding in position to the air circulation unit in order for a thermal conduction medium in the at least one condenser unit to receive heat from an airflow passing through the at least one condenser unit, each said condenser unit comprising a plurality of condensers, wherein each said condenser has a circulation tube system comprising a first main-channel aluminum tube, a second main-channel aluminum tube, and a plurality of aluminum flat tubes each having one end in communication with the first main-channel aluminum tube and an opposite end in communication with the second main-channel aluminum tube, wherein an airflow channel is formed between each two adjacent said aluminum flat tubes to enable air circulation, and each said airflow channel is provided therein with an aluminum fin, and wherein the condensers in each said condenser unit are horizontally arranged, and the airflow channels of the condensers in each said condenser unit are connected in series; and
a heat dissipation device in communication with the circulation tube systems and configured to receive the thermal conduction medium in the circulation tube systems and dissipate heat from the thermal conduction medium received.

2. The rear-door heat dissipation system with a horizontally arranged and series-connected design as claimed in claim 1, wherein the number of the plurality of condensers in each said condenser unit is two or greater than two.

3. The rear-door heat dissipation system with a horizontally arranged and series-connected design as claimed in claim 2, wherein the number of the at least one condenser unit is plural, and the plural condenser units are sequentially arranged in a downward direction.

4. The rear-door heat dissipation system with a horizontally arranged and series-connected design as claimed in claim 3, wherein the heat dissipation device comprises an inflow main duct and a return-flow main duct, and wherein the inflow main duct is connected to at least one input of the circulation tube systems of each of the plural condenser units, and the return-flow main duct is connected to at least one output of the circulation tube systems of each of the plural condenser units.

5. The rear-door heat dissipation system with a horizontally arranged and series-connected design as claimed in claim 4, wherein at least one separation wall is provided in each said first main-channel aluminum tube and/or each said second main-channel aluminum tube of an arbitrary one, or each of several, of the plural condenser units such that each said first main-channel aluminum tube provided with at least one said separation wall and/or each said second main-channel aluminum tube provided with at least one said separation wall is divided into at least two cavities sequentially arranged in the downward direction.

6. The rear-door heat dissipation system with a horizontally arranged and series-connected design as claimed in claim 5, wherein the input of the circulation tube systems of each of the plural condenser units is provided at a said first main-channel aluminum tube, and the output of the circulation tube systems of each of the plural condenser units is provided at a said second main-channel aluminum tube.

7. The rear-door heat dissipation system with a horizontally arranged and series-connected design as claimed in claim 5, wherein the input and the output of the circulation tube systems of each of the plural condenser units are provided at a said first main-channel aluminum tube.

8. The rear-door heat dissipation system with a horizontally arranged and series-connected design as claimed in claim 1, wherein the air circulation unit comprises a channel provided in the cabinet back door and a fan provided in the channel.

9. The rear-door heat dissipation system with a horizontally arranged and series-connected design as claimed in claim 1, wherein the first main-channel aluminum tubes, the second main-channel aluminum tubes, and the aluminum flat tubes are formed by aluminum extrusion.

10. The rear-door heat dissipation system with a horizontally arranged and series-connected design as claimed in claim 1, wherein each of the condensers has a thickness ranging from 10 mm to 40 mm.
